(19) United States
(12) Patent Application Publication
(10) Pub. No.: US 2024/0298511 A1
(43) Pub. Date: Sep. 5, 2024

(54) MASK ASSEMBLY AND METHOD OF MANUFACTURING DISPLAY APPARATUS

(71) Applicant: Samsung Display Co., Ltd., Yongin-si (KR)

(72) Inventor: Hyuneok Shin, Yongin-si (KR)

(73) Assignee: Samsung Display Co., Ltd., Yongin-si (KR)

(21) Appl. No.: 18/443,670

(22) Filed: Feb. 16, 2024

(30) Foreign Application Priority Data
Mar. 3, 2023 (KR) 10-2023-0028753

(51) Int. Cl. H10K 71/16; C23C 14/04; C23C 14/24; H10K 59/12

(52) U.S. Cl. CPC H10K 71/166; C23C 14/042; C23C 14/24; H10K 59/1201; H10K 71/164

(57) ABSTRACT

A mask assembly includes a mask frame including an opening area and a mask sheet. The mask sheet includes a first metal layer arranged on the mask frame and including a first opening, a second metal layer arranged on the first metal layer and including a plurality of second openings overlapping the first opening in a plan view, a third metal layer arranged on the second metal layer and including a plurality of third openings overlapping the first opening in a plan view, and a fourth metal layer arranged on the third metal layer and including a plurality of fourth openings overlapping the first opening in a plan view.

### CROSS-REFERENCE TO RELATED APPLICATION

This application claims priority to and benefits of Korean Patent Application No. 10-2023-0028753 under 35 U.S.C. § 119, filed on Mar. 3, 2023, in the Korean Intellectual Property Office (KIPO), the entire contents of which are incorporated herein by reference.

### BACKGROUND

### 1. Technical Field

Embodiments relate to a mask assembly, which may enable the precise deposition of a pattern and the prevention of a shadow phenomenon, and a method of manufacturing a display apparatus.

### 2. Description of the Related Art

Display apparatuses provide visual information such as an image or a video to users. With the development of various electronic devices such as computers and large TVs, various types of display apparatuses applicable thereto have been developed. Recently, mobility-based electronic devices are widely used, and not only compact electronic devices such as mobile phones, but also tablet personal computers (PCs) are widely used as mobile electronic devices.

A display apparatus includes a display area and a non-display area, and multiple light-emitting elements are arranged in the display area. The display apparatus may provide an image through light emitted by the light-emitting elements. The light-emitting elements are formed through deposition of deposition materials, and in this regard, an apparatus for manufacturing a display apparatus including a mask assembly may be used.

The background technology described above is technical information that the inventor possessed for the derivation of the disclosure or acquired in the derivation process of the disclosure, and it cannot be said that it is known technology disclosed to the general public before the filing of the disclosure.

### SUMMARY

Embodiments include a mask assembly, which may enable the precise deposition of a pattern and the prevention of a shadow phenomenon, and a method of manufacturing a display apparatus.

However, the objective to be solved by the disclosure is not limited to thereto.

Additional aspects will be set forth in part in the description which follows and, in part, will be apparent from the description, or may be learned by practice of the embodiments of the disclosure.

According to an embodiment, a mask assembly may include a mask frame including an opening area, and a mask sheet. The mask sheet may include a first metal layer arranged on the mask frame and including a first opening, a second metal layer arranged on the first metal layer and including a plurality of second openings overlapping the first opening in a plan view, a third metal layer arranged on the second metal layer and including a plurality of third openings overlapping the first opening in a plan view, and a fourth metal layer arranged on the third metal layer and including a plurality of fourth openings overlapping the first opening in a plan view.

In an embodiment, the first opening may be formed corresponding to a cell area of the mask sheet, and the first metal layer may be arranged along a perimeter of the cell area.

In an embodiment, the first metal layer and the third metal layer may include a same material.

In an embodiment, the first metal layer and the second metal layer may include different materials, and the first metal layer and the fourth metal layer may include different materials.

In an embodiment, the first metal layer may include invar.

In an embodiment, the second metal layer may include tantalum nitride (TaN).

In an embodiment, a coefficient of thermal expansion of the second metal layer may be in a range of about 3.0*10−6/K to about 4.0*10−6/K.

In an embodiment, the fourth metal layer may include titanium nitride (TiN).

In an embodiment, a thickness of the first metal layer may be greater than a thickness of the third metal layer.

In an embodiment, the thickness of the third metal layer may be greater than a thickness of the second metal layer and a thickness of the fourth metal layer.

In an embodiment, a thickness of the first metal layer may be in a range of about 10 μm to about 15 μm.

In an embodiment, a thickness of the third metal layer may be in a range of about 0.3 μm to about 0.7 μm.

In an embodiment, a thickness of each of the second metal layer and the fourth metal layer may be in a range of about 0.05 μm to about 0.15 μm.

In an embodiment, in a plan view, one of the plurality of second openings, a corresponding one of the plurality of third openings, and a corresponding one of the plurality of fourth openings may be arranged to overlap one another.

In an embodiment, in a plan view, the corresponding one of the plurality of fourth openings may be smaller than the corresponding one of the plurality of third openings, and the corresponding one of the plurality of third openings may be smaller than the one of the plurality of second openings.

According to an embodiment, a method of manufacturing a display apparatus may include arranging a display substrate in a chamber, manufacturing a mask assembly, arranging the mask assembly to face the display substrate, and depositing a deposition material on the display substrate by passing through the mask assembly. The manufacturing of the mask assembly may include sequentially stacking a first metal layer, a second metal layer, a third metal layer, and a fourth metal layer, the first metal layer and the third metal layer including a same material.

In an embodiment, the manufacturing of the mask assembly may further include dry etching the fourth metal layer to form a plurality of first openings, and wet etching the third metal layer to form a plurality of second openings. The plurality of second openings may overlap the plurality of first openings in a plan view.

In an embodiment, in the wet etching of the third metal layer, the second metal layer may be used as an etch stopper layer.

In an embodiment, the manufacturing of the mask assembly may further include arranging a protection member to cover the fourth metal layer and a portion of the second metal layer exposed by the plurality of second openings.

In an embodiment, the manufacturing of the mask assembly may further include wet etching the first metal layer to form an opening corresponding to a cell area and overlapping the plurality of first openings in a plan view using the second metal layer as an etch stopper layer.

Other aspects, features, and advantages than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description, taken in conjunction with the accompanying drawings, in which:

FIG. 1 is a schematic perspective view of a display apparatus according to an embodiment;

FIG. 2 is a schematic cross-sectional view of the display apparatus according to an embodiment;

FIG. 3 is a schematic cross-sectional view of an apparatus for manufacturing a display apparatus, according to an embodiment;

FIG. 4 is a schematic perspective view of a mask assembly according to an embodiment;

FIG. 5 is a schematic cross-sectional view of a mask sheet according to an embodiment, which may correspond to a cross-section of the mask sheet taken along line V-V′ of FIG. 4; and

FIGS. 6 to 12 are schematic cross-sectional views showing a method of manufacturing a display apparatus, according to an embodiment.

### DETAILED DESCRIPTION OF THE EMBODIMENTS

Reference will now be made in detail to embodiments of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the embodiments, and particular embodiments will be illustrated in the drawings and described in the detailed description section. The effect and features of the embodiments, and a method to achieve the same, will be clearer referring to the detailed descriptions below with the drawings. However, the embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Sizes of elements in the drawings may be exaggerated for convenience of explanation. For example, since sizes and thicknesses of elements in the drawings are arbitrarily illustrated for convenience of explanation, the following embodiments are not limited thereto.

In the following embodiment, the X-axis, the Y-axis, and the Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

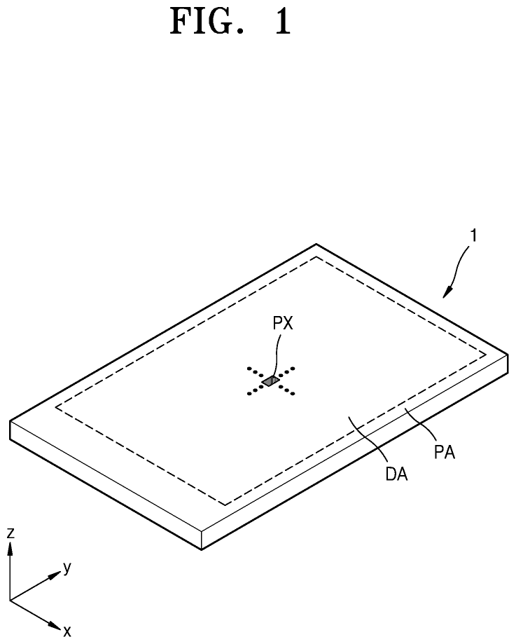

FIG. 1 is a schematic perspective view of a display apparatus 1 according to an embodiment.

Referring to FIG. 1, the display apparatus 1 may include a display area DA and a peripheral area PA arranged adjacent to the display area DA. The display apparatus 1 may provide an image through an array of multiple pixels PXs in the display area DA. The pixel PX may be defined as an emission area in which a light-emitting element driven by a pixel circuit emits light. For example, an image may be provided by the light emitted by light-emitting element through the pixel PX. Not only the light-emitting elements and the pixel circuits, but also various signal wires and power wires, and the like which are electrically connected to the pixel circuits may be arranged in the display area DA.

The peripheral area PA, which is an area that does not provide an image, may entirely or partially surround the display area DA. Various wires, a drive circuit, and the like to provide electrical signals or power to the display area DA may be arranged in the peripheral area PA.

The display apparatus 1 may have an approximately rectangular shape when viewed from a direction perpendicular to a surface thereof (in a plan view). For example, the display apparatus 1 may have, as illustrated in FIG. 1, generally a rectangular shape having a short side extending in an x direction, for example, and a long side extending in a y direction, for example, in a plan view. A corner where the short side the long side may have a right-angled shape, or a round shape having a curvature. However, the shape of the display apparatus 1 is not limited to a rectangular shape, and the display apparatus 1 may have various shapes including a polygonal shape such as a triangle, a circular shape, an oval shape, an amorphous shape, and the like in a plan view.

Although FIG. 1 illustrates that the display apparatus 1 includes a flat display surface, the disclosure is not limited thereto. In another embodiment, the display apparatus 1 may include a three-dimensional display surface or a curved display surface. In case that the display apparatus 1 includes a three-dimensional display surface, the display apparatus 1 may include multiple display areas in different directions, for example, a polygonal columnar display surface. In another embodiment, in case that the display apparatus 1 includes a curved display surface, the display apparatus 1 may be implemented in various shapes. For example, the display surface may be flexible, foldable, rollable, or the like.

The display apparatus 1 may be used as a display screen of not only portable electronic apparatuses, such as mobile phones, smartphones, tablet personal computers (PCs), mobile communication terminals, electronic organizers, electronic books, portable multimedia players (PMPs), navigation devices, ultra-mobile PCs (UMPCs), and the like, but various products, such as televisions, notebook computers, monitors, billboards, Internet of things (IoT), and the like. Furthermore, the display apparatus 1 according to an embodiment may be used in wearable devices, such as smart watches, watch phones, glasses type displays, and head mounted displays (HMDs). Furthermore, the display apparatus 1 according to an embodiment may be used as an instrument panel of a vehicle, a center information display (CID) disposed on the center fascia or dashboard of a vehicle, a room mirror display in lieu of a side mirror of a vehicle, or a display screen disposed at the rear surface of a front seat as an entertainment device for a rear seat of a vehicle.

In the following description, although the display apparatus 1 is described as including an organic light-emitting diode (OLED) as a light-emitting element, the display apparatus 1 is not limited thereto. In another embodiment, the display apparatus 1 may be a light-emitting display apparatus including an inorganic light-emitting diode, for example, an inorganic light-emitting display apparatus. In another embodiment, the display apparatus 1 may be a quantum-dot light-emitting display apparatus.

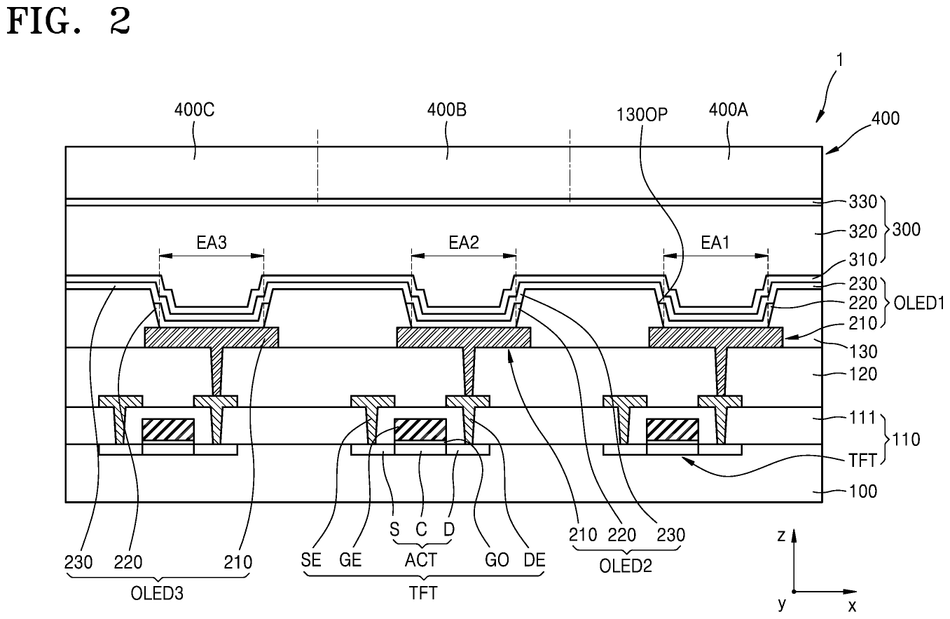

FIG. 2 is a schematic cross-sectional view of the display apparatus 1 according to an embodiment.

Referring to FIG. 2, the display apparatus 1 may include a substrate 100, a pixel circuit layer 110 including a thin film transistor TFT, a via insulating layer 120 on the pixel circuit layer 110, and first to third organic light-emitting diodes OLED1, OLED2, and OLED3 disposed on the via insulating layer 120. The display apparatus 1 may further include an encapsulation layer 300 disposed on the first to third organic light-emitting diodes OLED1, OLED2, and OLED3, and a color filter layer 400 disposed on the encapsulation layer 300.

The substrate 100 may have an upper surface extending in a plane defined by the x direction and the y direction. The substrate 100 may include a semiconductor material, for example, a Group IV semiconductor, a Group III-V compound semiconductor, or a Group II-VI compound semiconductor. The substrate 100 may include a silicon layer. For example, the substrate 100 may be a semiconductor substrate including a semiconductor material. However, the substrate 100 is not limited to a semiconductor substrate. For example, the substrate 100 may include glass or a polymer resin including polyethersulfone, polyarylate, polyetherimide, polyethylene naphthalate, polyethylene terephthalate, polyphenylene sulfide, polyimide, polycarbonate, cellulose triacetate, cellulose acetate propionate, the like, or a combination thereof. In an embodiment, the substrate 100 may have a multilayer structure including a barrier layer (not shown) and a base layer including the polymer resin described above. In the following description, a case in which the substrate 100 includes a semiconductor material is described in detail.

The pixel circuit layer 110 may be disposed on the substrate 100. The pixel circuit layer 110 may include a pixel circuit connected to the organic light-emitting diode OLED, and insulating layers. The pixel circuit layer 110 may include at least one thin film transistor TFT and an interlayer insulating layer 111, which are disposed on the substrate 100.

The thin film transistor TFT may include a gate dielectric layer GO, a gate electrode GE, and an active region ACT.

The active region ACT may be arranged within the substrate 100. For example, the active region ACT may be formed as a part of the substrate 100. The active region ACT may extend in a first direction, for example, the x direction, within the substrate 100. As a portion of the substrate 100 is recessed, the active region ACT may be disposed in the recess portion of the substrate 100. The active region ACT may include a channel region C and a drain region D and a source region S arranged at the opposite sides of the channel region C. Each of the drain region D and the source region S may be an area doped with an impurity in the substrate 100 including a semiconductor material. The channel region C may overlap the gate electrode GE in a plan view.

The gate dielectric layer GO may be arranged between the gate electrode GE and the active region ACT. The gate dielectric layer GO may include an inorganic insulating material, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The gate electrode GE may be disposed above the active region ACT. The gate electrode GE may extend in a direction, for example, the y direction, and intersect the active region ACT in a plan view. The channel region C of the thin film transistor TFT may be formed on the active region ACT intersecting the gate electrode GE in a plan view. The gate electrode GE may be disposed on the gate dielectric layer GO. The gate electrode GE may include a conductive material. For example, the gate electrode GE may include a metal nitride, such as a titanium nitride (TiN), a tantalum nitride (TaN), or a tungsten nitride (WN), and/or a metal, such as aluminum (Al), tungsten (W), copper (Cu), molybdenum (Mo) or the like, or a semiconductor material such as doped polysilicon. The gate electrode GE may be formed in a multilayer or single layer including the material described above.

The interlayer insulating layer 111 may be disposed on the substrate 100 and may cover the thin film transistor TFT. The interlayer insulating layer 111 may include at least one of oxide, nitride, and oxynitride. The interlayer insulating layer 111 may have a single layer or multilayer structure.

A drain electrode DE and a source electrode SE may be disposed on the interlayer insulating layer 111. The drain electrode DE and the source electrode SE may be connected to the drain region D and the source region S of the active region ACT, respectively, via contact holes in the interlayer insulating layer 111. The drain electrode DE and the source electrode SE may each include a material having excellent conductivity. The drain electrode DE and the source electrode SE may each include a conductive material such as Mo, Al, Cu, titanium (Ti), and the like, and may be formed in a multilayer or single layer including the material described above.

The via insulating layer 120 may be disposed on the pixel circuit layer 110. The via insulating layer 120 may cover the drain electrode DE and the source electrode SE. The via insulating layer 120 may include an organic insulating material, such as a general purpose polymer, such as polymethylmethacrylate (PMMA) and polystyrene (PS), a polymer derivative having a phenolic group, an acrylic polymer, an imide-based polymer, an arylether-based polymer, an amide-based polymer, a fluorine-based polymer, a p-xylene-based polymer, a vinyl alcohol-based polymer, and blends thereof.

The first to third organic light-emitting diodes OLED1, OLED2, and OLED3 may be disposed on the via insulating layer 120. The first to third organic light-emitting diodes OLED1, OLED2, and OLED3 may each have a stack structure of a pixel electrode 210, an emission layer 220, and a counter electrode 230. In an embodiment, the first to third organic light-emitting diodes OLED1, OLED2, and OLED3 may each emit white light. In another embodiment, the first to third organic light-emitting diodes OLED1, OLED2, and OLED3 may respectively emit red, green, and blue light, or may each emit one of red, green, blue, and white light. The first to third organic light-emitting diodes OLED1, OLED2, and OLED3 may emit light, and areas from which light is emitted may be defined as first to third emission areas EA1, EA2, and EA3.

The pixel electrode 210 may be disposed on the via insulating layer 120 and may be electrically connected to the thin film transistor TFT through a contact hole in the via insulating layer 120. The pixel electrodes 210 of the first to third organic light-emitting diodes OLED1, OLED2, and OLED3 may be arranged apart from each other.

The pixel electrode 210 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the pixel electrode 210 may include a reflective film including silver (Ag), magnesium (Mg), Al, platinum (Pt), palladium (Pd), gold (Au), nickel (Ni), neodymium (Nd), iridium (Ir), chromium (Cr), or a compound thereof. In another embodiment, the pixel electrode 210 may further include a film formed of ITO, IZO, ZnO, or In₂O₃ above/below the reflective film described above.

A pixel defining layer 130 having an opening 130OP exposing the center portion of the pixel electrode 210 may be disposed on the pixel electrode 210. The pixel defining layer 130 may include an organic insulating material and/or an inorganic insulating material. The opening 130OP may define an emission area of light emitted from each of the first to third organic light-emitting diodes OLED1, OLED2, and OLED3. For example, the size/width of the opening 130OP may correspond to the size/width of the emission area EA1, EA2, and EA3. Accordingly, the size and/or width of the pixel PX may depend on the size and/or width of the opening 130OP of the pixel defining layer 130 corresponding thereto.

The emission layer 220 may be disposed on the pixel electrode 210 corresponding to the pixel electrode 210. The emission layer 220 may include a polymer or a low molecular weight organic material for emitting light of a color. In another embodiment, the emission layer 220 may include an inorganic light-emitting material or quantum dots.

In an embodiment, a first function layer (not shown) and a second function layer (not shown) may be disposed below and above the emission layer 220. The first function layer may include, for example, a hole transport layer (HTL), or a HTL and a hole injection layer (HIL). The second function layer disposed on the emission layer 220 may include an electron transport layer (ETL) and/or an electron injection layer (EIL). The first function layer and/or the second function layer may be common layers formed to entirely cover the substrate 100 like the counter electrode 230 to be described below.

The counter electrode 230 may be disposed above the pixel electrode 210, and may overlap the pixel electrode 210 in a plan view. The counter electrode 230 may be disposed on the emission layer 220. The counter electrode 230 may include a conductive material having a low work function. For example, the counter electrode 230 may include a (semi-) transparent layer including Ag, Mg, Al, Pt, Pd, Au, Ni, Nd, Ir, Cr, lithium (Li), calcium (Ca), the like or an alloy thereof. In an example, the counter electrode 230 may further include a layer including ITO, IZO, ZnO, or In₂O₃ on the (semi-) transparent layer including the material described above. The counter electrode 230 may be integrally formed to entire cover the substrate 100.

The encapsulation layer 300 may be disposed on the counter electrode 230. The encapsulation layer 300 may be disposed to cover the organic light-emitting diodes OLED1, OLED2, and OLED3. The encapsulation layer 300 may include at least one inorganic encapsulation layer and at least one organic encapsulation layer. In an embodiment, the encapsulation layer 300 may include a first inorganic encapsulation layer 310, an organic encapsulation layer 320 on the first inorganic encapsulation layer 310, and a second inorganic encapsulation layer 330.

The first inorganic encapsulation layer 310 and the second inorganic encapsulation layer 330 may each include at least one inorganic material including Al₂O₃, TiO₂, Ta₂O₅, HfO₂, ZnO₂, SiO₂, SiN_{X}, and SiON. The organic encapsulation layer 320 may include a polymer-based material. In an embodiment, the organic encapsulation layer 320 may include an acrylic resin, an epoxy-based resin, polyimide, polyethylene, and the like. In an embodiment, the organic encapsulation layer 320 may include acrylate. The organic encapsulation layer 320 may be formed by curing a monomer or coating a polymer. The organic encapsulation layer 320 may have transparency.

The color filter layer 400 may be disposed on the encapsulation layer 300. The color filter layer 400 may include a first color filter 400A, a second color filter 400B, and a third color filter 400C. Each of the first to third color filters 400A, 400B, and 400C may be arranged to respectively correspond to the pixel electrodes 210 of the organic light-emitting diodes OLED1, OLED2, and OLED3. For example, the first color filter 400A may be arranged to overlap the pixel electrode 210 of the first organic light-emitting diode OLED1 in a direction perpendicular to the substrate 100, for example, in the z direction. For example, the second color filter 400B may be arranged to overlap the pixel electrode 210 of the second organic light-emitting diode OLED2 in a direction perpendicular to the substrate 100, for example, in the z direction. For example, the third color filter 400C may be arranged to overlap the pixel electrode 210 of the third organic light-emitting diode OLED3 in a direction perpendicular to the substrate 100, for example, in the z direction.

The first to third color filters 400A, 400B, and 400C may each include a photosensitive resin. The first to third color filters 400A, 400B, and 400C may each include pigment or dye having a color.

The first to third color filters 400A, 400B, and 400C may each transmit red, green, or blue light. For example, the first color filter 400A may be a red color filter that selectively transmits red light of the light emitted from the emission layer 220. For example, the first color filter 400A may pass only light of a wavelength in a range of about 630 nm to about 780 nm. For example, the second color filter 400B may be a green color filter that selectively transmits green light of the light emitted from the emission layer 220. For example, the second color filter 400B may pass only light of a wavelength in a range of about 495 nm to about 570 nm. For example, the third color filter 400C may be a blue color filter that selectively transmits blue light of the light emitted from the emission layer 220. For example, the third color filter 400C may pass only light of a wavelength in a range of about 450 nm to about 495 nm.

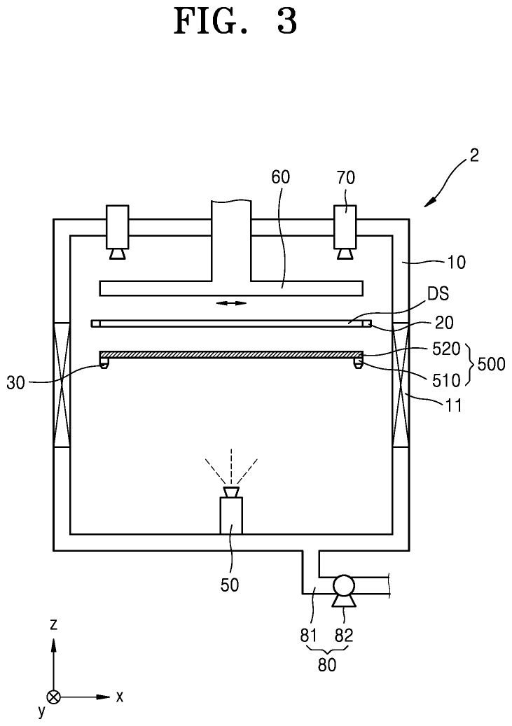

FIG. 3 is a schematic cross-sectional view of an apparatus 2 for manufacturing a display apparatus, according to an embodiment.

Referring to FIG. 3, the apparatus 2 for manufacturing a display apparatus may be used to manufacture the display apparatus 1 described above, but the disclosure is not limited thereto.

The apparatus 2 for manufacturing a display apparatus may include a chamber 10, a first support 20, a second support 30, a mask assembly 500, a deposition source 50, a magnetic force unit 60, a vision unit 70, and a pressure regulator 80.

A space may be formed in the chamber 10, and a display substrate DS and the mask assembly 500 may be accommodated in the space. A portion of the chamber 10 may be formed to be open, and a gate valve 11 may be installed in the open portion of the chamber 10. The open portion of the chamber 10 may be opened or closed according to the operation of the gate valve 11.

The display substrate DS, which is a part of a display apparatus in the manufacturing of the display apparatus, may be the substrate 100 in a state in which at least one of an organic layer, an inorganic layer, or a metal layer is deposited on the substrate 100 to be described below. In another embodiment, the display substrate DS may be the substrate 100 on which one of the organic layer, the inorganic layer, and the metal layer is deposed.

The first support 20 may support the display substrate DS. The first support 20 may be in the form of a plate fixed in the chamber 10. In another embodiment, the first support 20 may be in the form of a shuttle in which the display substrate DS is seated and which linearly moves in the chamber 10. In another embodiment, the first support 20 may include an electrostatic chuck or an adhesive chuck which is fixed in the chamber 10 or arranged in the chamber 10 and moves inside the chamber 10.

The second support 30 may support the mask assembly 500. The second support 30 may be disposed in the chamber 10. The second support 30 may finely adjust the position of the mask assembly 500. The second support 30 may include a separate driving unit, an alignment unit, or the like to move the mask assembly 500 in different directions.

In another embodiment, the second support 30 may be in the form of a shuttle, and the second support 30 may support the mask assembly 500 and transfer the mask assembly 500. For example, the second support 30 may move to the outside of the chamber 10, and support the mask assembly 500 and enter to the inside of the chamber 10 from the outside of the chamber 10.

In the embodiment, the first support 20 and the second support 30 may be integrally formed, and the first support 20 and the second support 30 may include a movable shuttle. The first support 20 and the second support 30 may have a structure to fix the mask assembly 500 and the display substrate DS while the display substrate DS is seated on the mask assembly 500, and may linearly move the display substrate DS and the mask assembly 500 at the same time.

In the following description, for convenience of explanation, an embodiment in which the first support 20 and the second support 30 are separately formed and arranged at different positions in the chamber 10 is described in detail.

The deposition source 50 may be arranged to face the mask assembly 500. The deposition source 50 may accommodate a deposition material, and apply heat to the deposition material to evaporate or sublimate the deposition material. The deposition source 50 may be fixed in the chamber 10 or arranged in the chamber 10 and linearly movable in a direction.

The mask assembly 500 may be arranged in the chamber 10. The mask assembly 500 may include a mask frame 510 and a mask sheet 520, which is described below in detail. The deposition material may pass through the mask assembly 500 and deposited on the display substrate DS. In an embodiment, the deposition material may pass through the mask assembly 500 and form the emission layer 220 described above.

The magnetic force unit 60 may be arranged in the chamber 10 to face the display substrate DS and/or the mask assembly 500. The magnetic force unit 60 may apply a force to the mask assembly 500 toward the display substrate DS by applying a magnetic force to the mask assembly 500. For example, the magnetic force unit 60 may prevent sagging of the mask sheet 520, and also make the mask sheet 520 close to display substrate DS. For example, the magnetic force unit 60 may maintain a uniform distance between the mask sheet 520 and the display substrate DS.

The vision unit 70 may be arranged in the chamber 10 and may detect the positions of the display substrate DS and the mask assembly 500. The vision unit 70 may include a camera for capturing images of the display substrate DS and the mask assembly 500. Based on the image captured by the vision unit 70, the positions of the display substrate DS and the mask assembly 500 may be identified, and the deformation of the mask assembly 500 may be confirmed. Furthermore, based on the image captured by the vision unit 70, the first support 20 may finely adjust the position of the display substrate DS or the second support 30 may finely adjust the position of the mask assembly 500. In the following description, an embodiment in which the second support 30 finely adjust the position of the mask assembly 500 to align the arrangement of the display substrate DS and the mask assembly 500 is described in detail.

The pressure regulator 80 may be connected to the chamber 10 and may regulate the pressure in the chamber 10. For example, the pressure regulator 80 may regulate the pressure in the chamber 10 to be the same as or similar to the atmospheric pressure. For example, the pressure regulator 80 may regulate the pressure in the chamber 10 to be the same as or similar to the vacuum state.

The pressure regulator 80 may include a connection pipe 81 connected to the chamber 10 and a pump 82 installed on the connection pipe 81. According to the operation of the pump 82, external air may be introduced through the connection pipe 81 or a gas in the chamber 10 may be moved to the outside through the connection pipe 81.

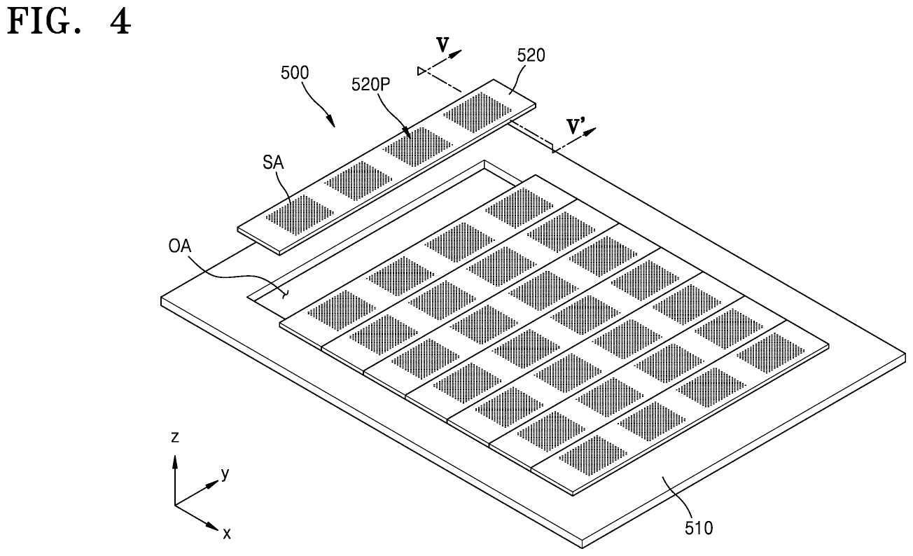

FIG. 4 is a schematic perspective view of the mask assembly 500 according to an embodiment.

Referring to FIG. 4, the mask assembly 500 may include the mask frame 510 and the mask sheet 520.

The mask frame 510 may be formed by connecting multiple sides, and may include an opening area OA defined by the sides. For example, the opening area OA may be surrounded by the sides, and the opening area OA may be formed by penetrating the center of the mask frame 510. A support stick (not shown) may be arranged in parallel in a direction and cross the mask frame 510, for example, the opening area OA, of the mask frame 510. In another embodiment, the support stick that crosses the opening area OA may be of a grid type.

The mask frame 510 may have a rectangular shape in a plan view in an embodiment. However, the disclosure is not limited thereto, and the shape of the mask frame 510 is not limited thereto and may be provided in various types of polygonal shapes. In the following description, for convenience of explanation, an embodiment in which the mask frame 510 has a rectangular shape in a plan view is described.

The mask sheet 520 may be disposed on the mask frame 510. For example, the mask sheet 520 may be arranged to cover the opening area OA of the mask frame 510. In an embodiment, the mask sheet 520 may include at least one mask sheet. In case that the mask sheet 520 includes two or more mask sheets, the mask sheets 520 may be arranged parallel to each other on the mask frame 510. For example, the mask sheets 520 may be arranged parallel to each other in a direction (for example, an x direction of FIG. 4), and may extend in another direction (for example, a y direction of FIG. 4) intersecting the direction. In an embodiment, the mask sheets 520 may be fixed on the mask frame 510 by a welding method.

The mask sheet 520 may include an opening pattern 520P for depositing a deposition material on the display substrate DS. The display substrate DS may be a part of a display apparatus in the manufacturing of the display apparatus. In an embodiment, the display substrate DS, as a mother substrate, may include multiple cells. The cells may be cut to form multiple display apparatuses. For example, a deposition material may be deposited on the cells of the display substrate DS, and the display substrate DS may be cut along the cells, thereby manufacturing multiple display apparatuses.

The opening pattern 520P may be arranged in an area corresponding to each cell of the display substrate DS. For example, the opening pattern 520P may be arranged in a cell area SA of the mask sheet 520. The opening pattern 520P may include multiple through-holes, as illustrated in FIG. 4. The opening pattern 520P may correspond to, for example, a pattern of an emission layer that forms the emission layer of a display apparatus. The display apparatus described above may be a display apparatus implementing an ultra-high resolution in an embodiment. The minimum width of a portion of the emission layer of the display apparatus may be less than or equal to about 3 μm. For example, the minimum width of a portion of the emission layer of the display apparatus may be in a range of about 2 μm to about 3 μm. However, the disclosure is not limited thereto, and the minimum width of a portion of the emission layer may be less than or equal to about 2 μm.

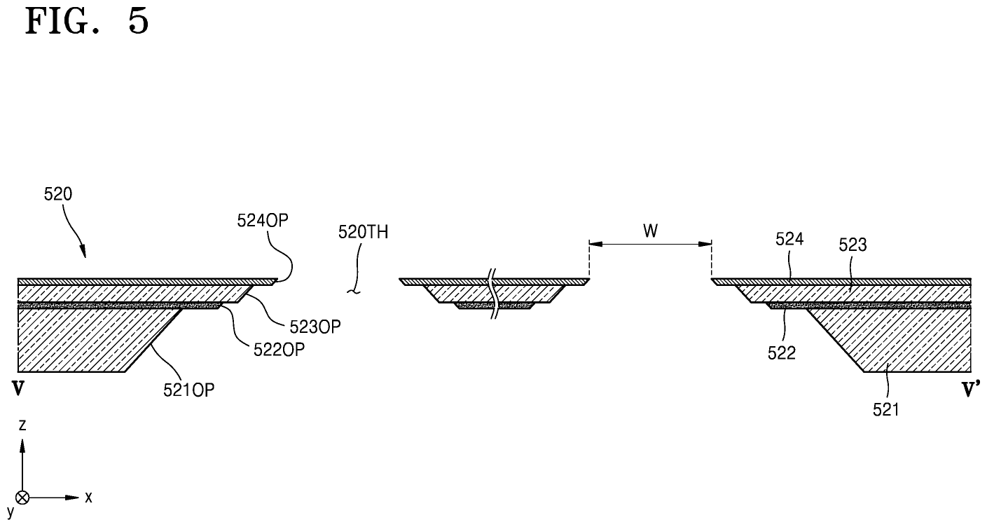

FIG. 5 is a schematic cross-sectional view of a mask sheet according to an embodiment, which may correspond to a cross-section of the mask sheet taken along line V-V′ of FIG. 4. FIG. 5 schematically illustrates a through-hole 520TH forming the opening pattern 520P.

Referring to FIG. 5, the mask sheet 520 may include a first metal layer 521, a second metal layer 522, a third metal layer 523, and a fourth metal layer 524.

The first metal layer 521 may be arranged on the mask frame 510. The first metal layer 521, as a support layer of the mask sheet 520, may include invar. The invar may be an alloy of iron and nickel in which a nickel content is, for example, about 37%. As the invar has a relatively low thermal expansion coefficient, the first metal layer 521 may reduce thermal deformation while maintaining mechanical strength of the mask sheet 520.

In an embodiment, the first metal layer 521 may include a first opening 521OP. The first opening 521OP may be an opening corresponding to a cell area SA. For example, the first opening 521OP may overlap the cell area SA in a plan view. Accordingly, the first metal layer 521 may surround the cell area SA in a plan view.

In an embodiment, the inner surface of the first opening 521OP may be sloped. For example, the radius of the through hole 520TH may decrease as a distance from a lower surface of the first metal layer 521 increases. The slope of the inner surface of the first opening 521OP may prevent a shadow phenomenon even to various incident angles of a deposition material.

In an embodiment, a thickness of the first metal layer 521 may be in a range of about 10 μm to about 15 μm. For example, the thickness of the first metal layer 521 may be about 15 μm. As the first metal layer 521 is arranged along the perimeter of the cell area SA, even in case that the first metal layer 521 has a thickness greater than thicknesses of the second metal layer 522 to the fourth metal layer 524, the first metal layer 521 may reinforce mechanical strength of the mask sheet 520 without causing the shadow phenomenon.

The second metal layer 522 may be disposed on the first metal layer 521. The second metal layer 522 may be used as an etch stopper during the first opening 521OP of the first metal layer 521 is generated in the manufacturing process of the mask sheet 520 to be described below. In an embodiment, the second metal layer 522 may include at least one of tantalum nitride (TaN) and titanium nitride (TiN). For example, the second metal layer 522 may include TaN and have a low thermal expansion coefficient. In an embodiment, the thermal expansion coefficient of the second metal layer 522 may be in a range of about 3.0*10−6/K to about 4.0*10−6/K. For example, the thermal expansion coefficient of the second metal layer 522 may be about 3.6*10−6/K.

In an embodiment, the second metal layer 522 may include a second opening 522OP. The second opening 522OP may be provided in plural, and the second openings 522OP may be arranged in a cell area SA. Furthermore, the second openings 522OP may overlap the first opening 521OP in a plan view, and may be arranged within the perimeter of the first opening 521OP.

Furthermore, the inner surface of the second opening 522OP may be sloped. For example, the radius of the second opening 522OP may decrease as a distance from a lower surface of the second metal layer 522 increases. The slope of the inner surface of the second opening 522OP may prevent the shadow phenomenon even to various incident angles of a deposition material.

In an embodiment, a thickness of the second metal layer 522 may be in a range of about 0.05 μm to about 0.15 μm. For example, the thickness of the second metal layer 522 may be about 0.1 μm. For example, the thickness of the second metal layer 522 may be less than the thickness of the first metal layer 521.

The third metal layer 523 may be disposed on the second metal layer 522. The third metal layer 523 may reduce thermal deformation of the mask sheet 520 while supporting the mask sheet 520. The third metal layer 523 and the first metal layer 521 may include a same material, and in an embodiment, the third metal layer 523 may include invar. As the invar has a relatively low thermal expansion coefficient, the third metal layer 523 may reduce thermal deformation while maintaining the mechanical strength of the mask sheet 520.

In an embodiment, the third metal layer 523 may include a third opening 523OP. The third opening 523OP may be provided in plural, and the third openings 523OP may be arranged in a cell area SA. In an embodiment, the third openings 523OP may overlap the first opening 521OP in a plan view, and may be arranged within the perimeter of the first opening 521OP in a plan view. In an embodiment, each of the third openings 523OP may overlap each of the second openings 522OP in a plan view, thereby forming the through-hole 520TH. The size of the third opening 523OP may be less than the size of the second opening 522OP. For example, in a plan view, the third opening 523OP may be arranged within the perimeter of the second opening 522OP.

In an embodiment, the inner surface of the third opening 523OP may be sloped. For example, the radius of the third opening 523OP may decrease as a distance from a lower surface of the third metal layer 523 increases. The slope of the inner surface of the third opening 523OP may prevent the shadow phenomenon even to various incident angles of a deposition material.

In an embodiment, the thickness of the third metal layer 523 may be in a range of about 0.3 μm to about 0.7 μm. For example, the thickness of the third metal layer 523 may be about 0.5 μm. For example, the thickness of the third metal layer 523 may be less than the thickness of the first metal layer 521 and greater than the thickness of the second metal layer 522.

As such, the mask sheet 520 according to an embodiment may include a double invar layer, for example, the first metal layer 521 and the third metal layer 523. The first opening 521OP of the first metal layer 521 may be formed corresponding to the size of the cell area SA, and the first metal layer 521 may serve as a support layer. The third metal layer 523 that substantially forms the through-hole 520TH through which the deposition material finally passes may be formed in a thin invar layer so that the shadow phenomenon may be prevented and heat resistance and mechanical strength may be reinforced.

The fourth metal layer 524 may be disposed on the third metal layer 523. The fourth metal layer 524 may be a final layer through which the deposition material passes, and may protect the outer surface of the mask sheet 520. In an embodiment, the fourth metal layer 524 may include TiN. TiN may be a hard material having a Mohs hardness of greater than or equal to about 9, and may protect the mask sheet 520 from being scratched by external impacts or the like.

In an embodiment, the fourth metal layer 524 may include a fourth opening 524OP. The fourth opening 524OP may be provided in plural, and the fourth openings 524OP may be arranged in a cell area SA. In an embodiment, the fourth openings 524OP may overlap the first opening 521OP in a plan view, and may be arranged within the perimeter of the first opening 521OP in a plan view. In an embodiment, each of the fourth openings 524OP may overlap each of the second openings 522OP and each of the third openings 523OP in a plan view, thereby forming the through-hole 520TH. The size of the fourth opening 524OP may be less than the size of the third opening 523OP. For example, in a plan view, the fourth opening 524OP may be arranged within the perimeter of the third opening 523OP.

In an embodiment, the minimum width W of a portion of the fourth opening 524OP may be less than or equal to about 3 μm. For example, the minimum width W of a portion of the fourth opening 524OP may be in a range of about 2 μm to about 3 μm. The width W of the fourth opening 524OP may correspond to the size of the emission layer of the display apparatus described above. For example, as the deposition material passes through the fourth opening 524OP and deposited on the display substrate DS, a micro emission layer for an ultra-high resolution may be formed.

In an embodiment, the inner surface of the fourth opening 524OP may be sloped. For example, the radius of the fourth opening 524OP may decrease as a distance from the fourth metal layer 524 increases. The slope of the inner surface of the fourth opening 524OP may prevent the shadow phenomenon even to various incident angles of a deposition material.

In an embodiment, the thickness of the fourth metal layer 524 may be in a range of about 0.05 μm to about 0.15 μm. For example, the thickness of the fourth metal layer 524 may be about 0.1 μm. In an embodiment, the thickness of the fourth metal layer 524 and the thickness of the second metal layer 522 may be same, and the thickness of the fourth metal layer 524 may be less than the thickness of the first metal layer 521 and the thickness of the third metal layer 523.

As such, in the mask sheet 520 according to an embodiment, the sum of the thicknesses of the second metal layer 522 to the fourth metal layer 524 substantially forming the through-hole 520TH may be less than about 1 μm. Accordingly, as the mask sheet 520 having a very thin structure is provided in the cell area SA where the opening pattern 520P is formed, the shadow phenomenon may be prevented and deposition quality may be improved. Furthermore, thermal deformation may be prevented through an invar layer with a strong mechanical strength, for example, the first metal layer 521 and the third metal layer 523.

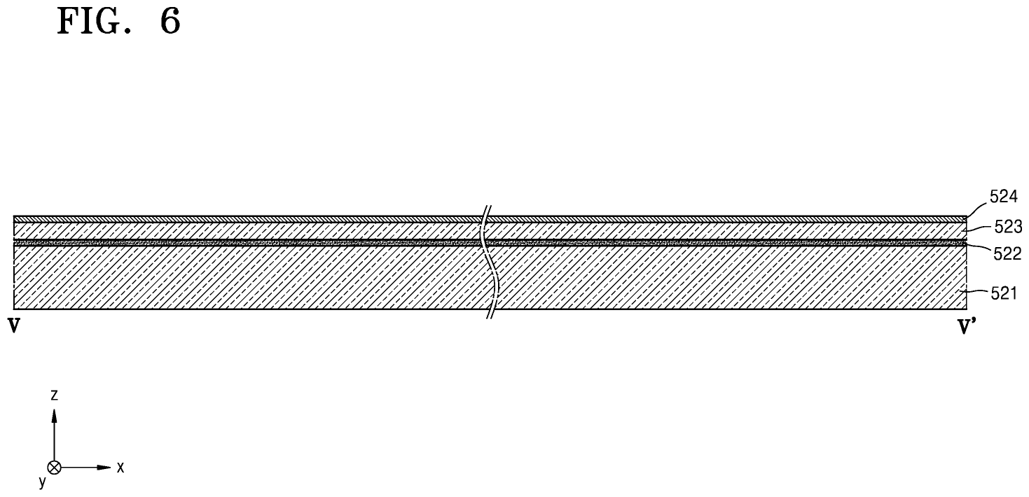

FIGS. 6 to 12 are schematic cross-sectional views showing a method of manufacturing a display apparatus, according to an embodiment. The method of manufacturing a display apparatus according to an embodiment may be used to manufacture the display apparatus described above, but the disclosure is not limited thereto.

Referring to FIG. 6, an apparatus for manufacturing a display apparatus, for example, the mask sheet 520, may be manufactured. The first metal layer 521, the second metal layer 522, the third metal layer 523, and the fourth metal layer 524 may be sequentially stacked. As described above, the first metal layer 521 and the third metal layer 523 may each include invar. The second metal layer 522 may include TaN, and the fourth metal layer 524 may include TiN.

In an embodiment, the second metal layer 522 may be formed on the first metal layer 521 by a vapor deposition method, for example, sputtering. The third metal layer 523 may be formed on the second metal layer 522 by an electro-forming method. The fourth metal layer 524 may be formed on the third metal layer 523 by a vapor deposition method, for example, sputtering.

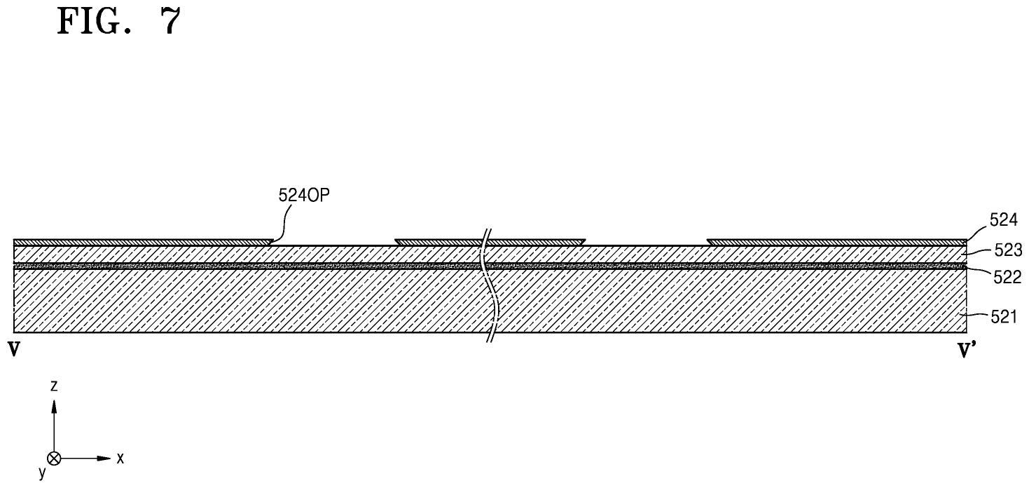

Referring to FIG. 7, a portion of the fourth metal layer 524 may be dry etched to form the fourth opening 524OP. The fourth metal layer 524, which is a final layer through which the deposition material passes, may be arranged closest to the display substrate DS. Accordingly, the fourth opening 524OP may be formed as a micro opening suitable for deposition for an ultra-high resolution through dry etching that is capable of precision processing.

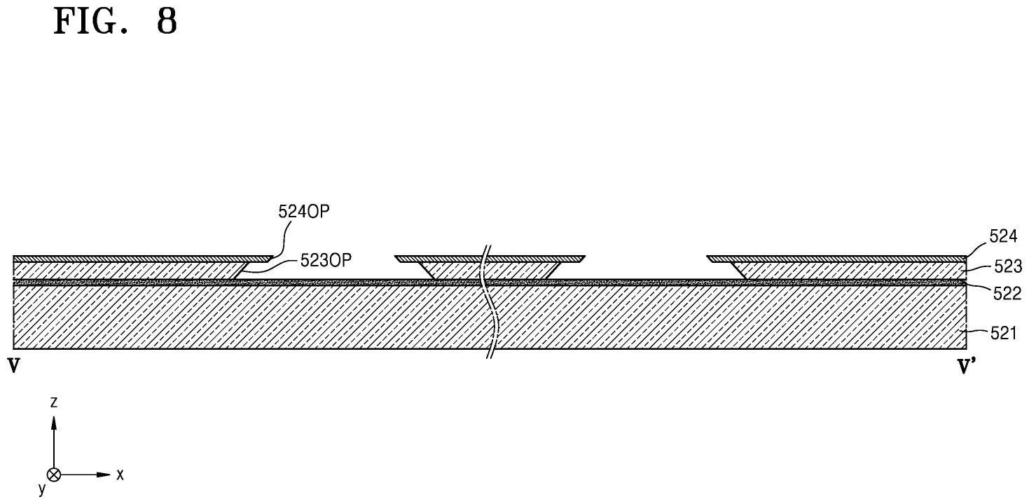

Referring to FIG. 8, a portion of the third metal layer 523 may be wet etched to form the third opening 523OP. The third opening 523OP may be formed to overlap the fourth opening 524OP in a plan view. Furthermore, the third opening 523OP having a size greater than the fourth opening 524OP may be formed through wet etching. During forming of the third opening 523OP, the second metal layer 522 may serve as an etch stopper to prevent layers below the third metal layer 523 from being etched. For example, the second metal layer 522 may include TiN, and TiN may not be etched by an etchant of the third metal layer 523 including invar.

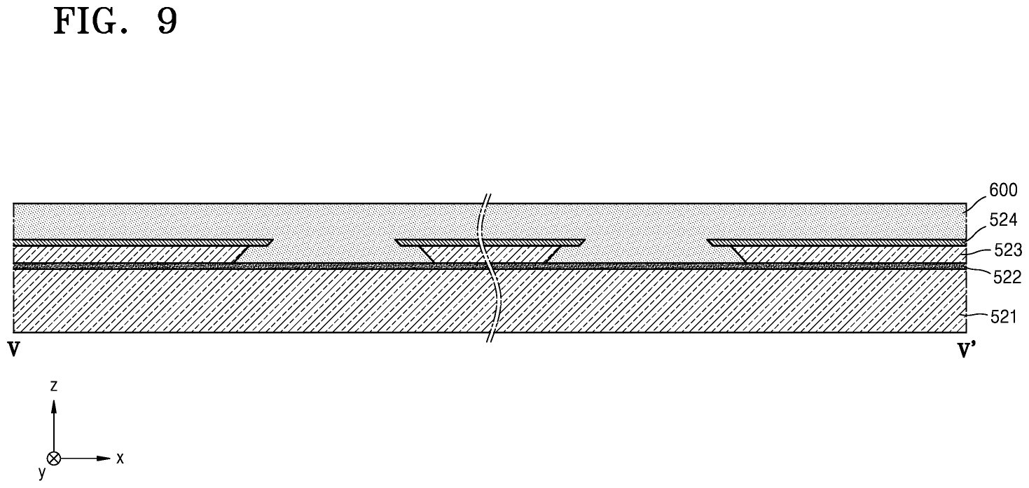

Referring to FIG. 9, a protection member 600 may be arranged to cover the top surface of the fourth metal layer 524. The protection member 600 may cover the fourth metal layer 524, and cover an upper surface of the second metal layer 522 exposed by the fourth opening 524OP and the third opening 523OP. The protection member 600 described above may protect not only the fourth metal layer 524, but also the fourth opening 524OP and the third opening 523OP that are etched, in the manufacturing process of the mask sheet 520.

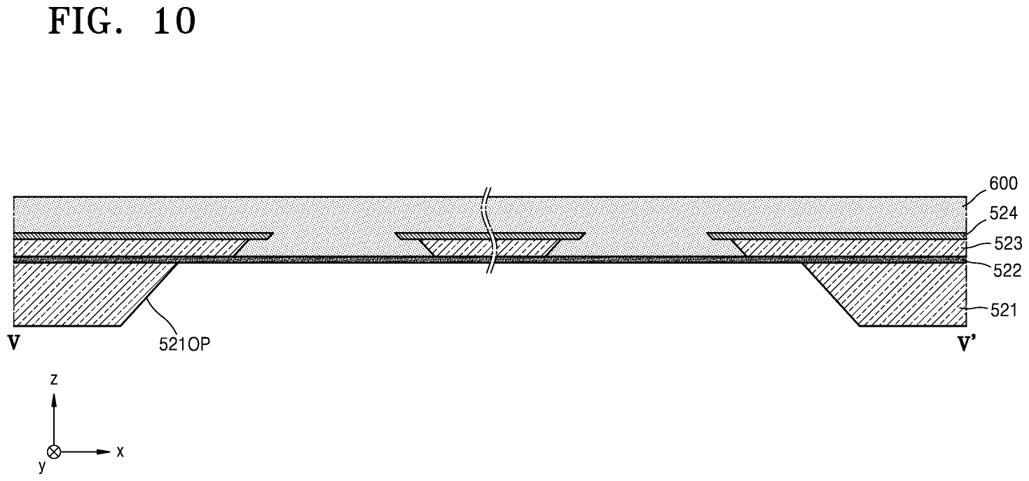

Referring to FIG. 10, a portion of the first metal layer 521 may be wet etched to form the first opening 521OP. The first opening 521OP may be formed in a size corresponding to the cell area SA, as described above. During forming of the first opening 521OP, the second metal layer 522 may serve as an etch stopper to prevent layers above the first metal layer 521 from being etched. For example, the second metal layer 522 may include TiN, and TiN may be not etched by an etchant of the first metal layer 521 including invar.

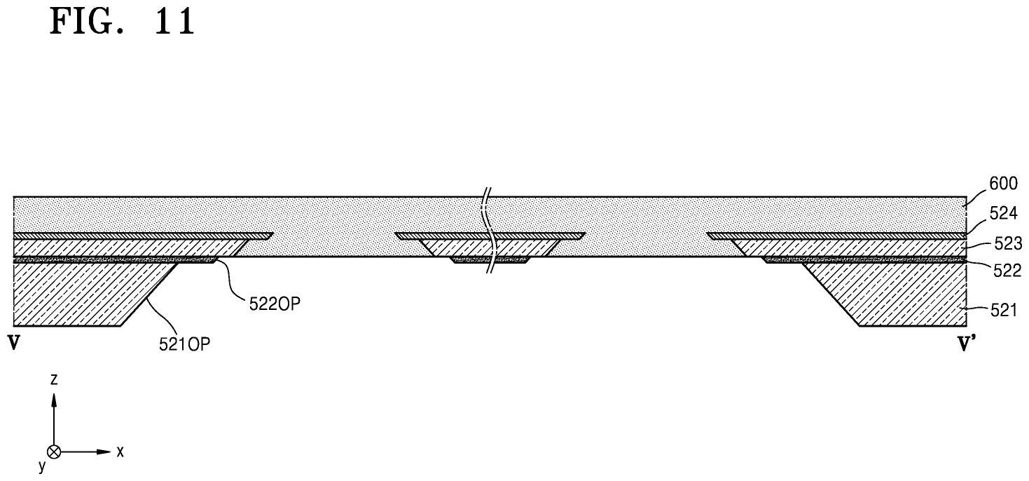

Referring to FIG. 11, a portion of the second metal layer 522 may be dry etched to form the second opening 522OP. The second opening 522OP may be formed to overlap the fourth opening 524OP and the third opening 523OP in a plan view. Furthermore, the size of the second opening 522OP may be formed to be greater than the size of the third opening 523OP.

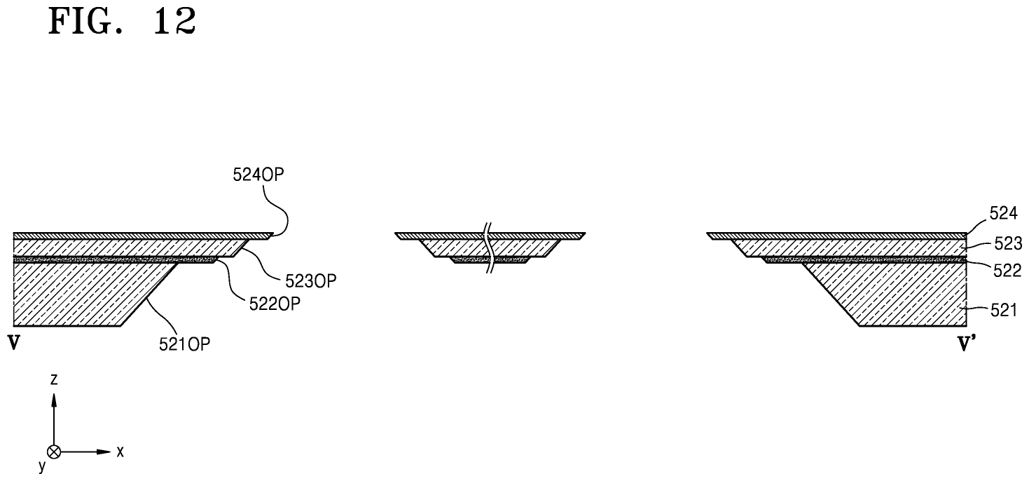

Referring to FIG. 12, the protection member 600 may be removed, and thus, the mask sheet 520 described above may be manufactured.

Referring back to FIG. 3, the display apparatus 1 may be manufactured by using the mask sheet 520 manufactured by the method described above.

In detail, in the method of manufacturing a display apparatus by using the apparatus 2 for manufacturing a display apparatus, including the mask sheet 520 as described above, first, the display substrate DS may be prepared.

The pressure regulator 80 may maintain the inside of the chamber 10 in a state same as or similar to the atmospheric pressure, and as the gate valve 11 operates, the open portion of the chamber 10 may be opened.

The display substrate DS may be loaded into the chamber 10 from the outside. The display substrate DS may be loaded into the chamber 10 by a method. For example, the display substrate DS may be loaded into the chamber 10 from the outside of the chamber 10 by a robot arm or the like arranged outside the chamber 10. In another embodiment, in case that the first support 20 is in the form of a shuttle, the first support 20 may be carried out from the inside of the chamber 10, the display substrate DS may be seated on the first support 20 by a separate robot arm or the like arranged outside the chamber 10, and the first support 20 may be loaded into the chamber 10 from the outside.

The mask assembly 500 may be arranged in the chamber 10 as described above. In another embodiment, the mask assembly 500 may be loaded into the chamber 10 from the outside in the same or similar manner to the display substrate DS.

During the display substrate DS is loaded into the chamber 10, the display substrate DS may be seated on the first support 20. The vision unit 70 may detect the positions of the display substrate DS and the mask assembly 500. The positions of the display substrate DS and the mask assembly 500 may be identified based on the image captured by the vision unit 70. The apparatus 2 for manufacturing a display apparatus may include a separate controller (not shown) so that the positions of the display substrate DS and the mask assembly 500 may be identified.

After the identification of the positions of the display substrate DS and the mask assembly 500 is completed, the second support 30 may finely adjust the position of the mask assembly 500.

As the deposition source 50 operates, the deposition material may be supplied toward the mask assembly 500, and the deposition material having passed through multiple pattern holes of the mask sheet 520 may be deposited on the display substrate DS. The deposition source 50 may move parallel to the display substrate DS and the mask assembly 500, or the display substrate DS and the mask assembly 500 may move parallel to the deposition source 50. For example, the deposition source 50 may move relative to the display substrate DS and the mask assembly 500. The pump 82 may maintain the pressure in the chamber 10 same or similar state to the vacuum by sucking the gas inside the chamber 10 and discharging the gas to the outside.

As described above, the deposition material supplied from the deposition source 50 may pass through the mask assembly 500 and deposited on the display substrate DS. Accordingly, at least one of the layers, for example, an organic layer, an inorganic layer, and a metal layer, to be stacked on the display apparatus described above may be formed.

According to an embodiment, provided are a mask assembly, which may enable the precise deposition of a pattern and the prevention of a shadow phenomenon, and a method of manufacturing a display apparatus.

The effects of the disclosure are not limited to the above-described effects, and other various effects that are not described in the specification may be clearly understood from the following descriptions by one skilled in the art to which the present disclosure belongs.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask assembly comprising:
a mask frame including an opening area; and
a mask sheet,
wherein the mask sheet comprises:
a first metal layer arranged on the mask frame and including a first opening;
a second metal layer arranged on the first metal layer and including a plurality of second openings overlapping the first opening in a plan view;
a third metal layer arranged on the second metal layer and including a plurality of third openings overlapping the first opening in a plan view; and
a fourth metal layer arranged on the third metal layer and including a plurality of fourth openings overlapping the first opening in a plan view.

2. The mask assembly of claim 1, wherein
the first opening is formed corresponding to a cell area of the mask sheet, and
the first metal layer is arranged along a perimeter of the cell area.

3. The mask assembly of claim 1, wherein the first metal layer and the third metal layer comprise a same material.

4. The mask assembly of claim 1, wherein
the first metal layer and the second metal layer comprise different materials, and
the first metal layer and the fourth metal layer comprise different materials.

5. The mask assembly of claim 1, wherein the first metal layer comprises invar.

6. The mask assembly of claim 1, wherein the second metal layer comprises tantalum nitride (TaN).

7. The mask assembly of claim 1, wherein a coefficient of thermal expansion of the second metal layer is in a range of about 3.0*10−6/K to about 4.0*10−6/K.

8. The mask assembly of claim 1, wherein the fourth metal layer comprises titanium nitride (TiN).

9. The mask assembly of claim 1, wherein a thickness of the first metal layer is greater than a thickness of the third metal layer.

10. The mask assembly of claim 9, wherein the thickness of the third metal layer is greater than a thickness of the second metal layer and a thickness of the fourth metal layer.

11. The mask assembly of claim 1, wherein a thickness of the first metal layer is in a range of about 10 μm to about 15 μm.

12. The mask assembly of claim 1, wherein a thickness of the third metal layer is in a range of 0.3 μm to about 0.7 μm.

13. The mask assembly of claim 1, wherein a thickness of each of the second metal layer and the fourth metal layer is in a range of about 0.05 μm to about 0.15 μm.

14. The mask assembly of claim 1, wherein, in a plan view, one of the plurality of second openings, a corresponding one of the plurality of third openings, and a corresponding one of the plurality of fourth openings are arranged to overlap one another.

15. The mask assembly of claim 14, wherein, in a plan view,
the corresponding one of the plurality of fourth opening is smaller than the corresponding one of the plurality of third openings, and
the corresponding one of the plurality of third openings is smaller than the one of the plurality of second openings.

16. A method of manufacturing a display apparatus, the method comprising:
arranging a display substrate in a chamber;
manufacturing a mask assembly;
arranging the mask assembly to face the display substrate; and
depositing a deposition material on the display substrate by passing through the mask assembly,
wherein the manufacturing of the mask assembly comprises sequentially stacking a first metal layer, a second metal layer, a third metal layer, and a fourth metal layer, the first metal layer and the third metal layer comprising a same material.

17. The method of claim 16, wherein
the manufacturing of the mask assembly further comprises:
dry etching the fourth metal layer to form a plurality of first openings; and
wet etching the third metal layer to form a plurality of second openings,
the plurality of second openings overlap the plurality of first openings in a plan view.

18. The method of claim 17, wherein, in the wet etching of the third metal layer, the second metal layer is used as an etch stopper layer.

19. The method of claim 17, wherein the manufacturing of the mask assembly further comprises arranging a protection member to cover the fourth metal layer and a portion of the second metal layer exposed by the plurality of second openings.

20. The method of claim 19, wherein the manufacturing of the mask assembly further comprises wet etching the first metal layer to form an opening corresponding to a cell area and overlapping the plurality of first openings in a plan view using the second metal layer as an etch stopper layer.
